(19) United States
(12) Patent Application Publication
(10) Pub. No.: US 2022/0231208 A1
(43) Pub. Date: Jul. 21, 2022

(54) COMPOSITE LEAD FRAME AND LIGHT-EMITTING DIODE PACKAGE STRUCTURE INCLUDING THE SAME

(71) Applicant: CHANG WAH TECHNOLOGY CO., LTD., Kaohsiung City (TW)

(72) Inventor: Chia-Neng HUANG, Kaohsiung City (TW)

(21) Appl. No.: 17/501,531

(22) Filed: Oct. 14, 2021

(30) Foreign Application Priority Data
Jan. 20, 2021 (TW) 110200689

(51) Int. Cl. H01L 33/60; H01L 33/62

(52) U.S. Cl. CPC H01L 33/60; H01L 33/62

(57) ABSTRACT

A composite lead frame for mounting a light-emitting diode chip thereon includes a chip mounting seat having at least two electrodes spaced apart from each other by a gap and configured to electrically connect with the LED chip. Each electrode is formed with at least one through hole. A plurality of fillers made of polymer materials are filled in the gap and the through hole. A reflector cup is disposed on and cooperates with the electrodes to define a receiving space for receiving the LED chip. The reflector cup is composed of a silicon-based polymer material and a white inorganic filling material, and is connected to the electrodes and the fillers. A LED package structure including the composite lead frame is also disclosed.

### CROSS-REFERENCE TO RELATED APPLICATION

This application claims priority of Taiwanese Utility Model Patent Application No. 110200689, filed on Jan. 20, 2021.

### FIELD

The disclosure relates to a lead frame and a package structure, and more particularly to a composite lead frame having a reflector cup and a light-emitting diode package structure including the composite lead frame for packaging a diode chip.

### BACKGROUND

A conventional lead frame package for high luminance light-emitting diode element is generally made by etching or stamping a metallic material, such as copper alloy or aluminum alloy, into a flat lead frame, after which a molding compound, such as an epoxy molding compound (EMC), is injection molded on a surface of the lead frame to form a packaging cup for reflecting light emitted from the light-emitting diode element.

Although the epoxy molding compound has good mechanical property and good metal bonding, it has poor weather resistance and poor light stability. As the use time increases, the originally white epoxy molding compound of the packaging cup used for reflecting the light will begin to age, to yellow and deteriorate, thereby gradually reducing reflectivity of light of the packaging cup and shortening the service life of the conventional lead frame package.

### SUMMARY

Therefore, an object of the present disclosure is to provide a composite lead frame that can alleviate at least one of the drawbacks of the prior art.

According to one aspect of this disclosure, a composite lead frame for mounting a light-emitting diode chip thereon includes a chip mounting seat, a plurality of fillers, and a reflector cup.

The chip mounting seat includes at least two electrodes spaced apart from each other by a gap and configured to electrically connect with the light-emitting diode chip. Each electrode has a plate shape with an upper surface, a lower surface opposite to the upper surface, and at least one through hole extending from the upper surface to the lower surface.

The fillers are made of polymer materials and are filled in the gap and the at least one through hole.

The reflector cup is disposed on and cooperates with the upper surfaces of the electrodes to define a receiving space for receiving the light-emitting diode chip. The reflector cup is made of a material different from that of the filler, and is composed of a silicon-based polymer material and a white inorganic filling material. The reflector cup is simultaneously connected to the electrodes and the fillers filled in the gap and the at least one through hole.

Another object of the present disclosure is to provide a light-emitting diode package structure that can alleviate at least one of the drawbacks of the prior art.

According to another aspect of this disclosure, a light-emitting diode package structure includes the composite lead frame as described above, a light-emitting diode unit, and an encapsulant. The light-emitting diode unit includes a light-emitting diode chip mounted on the upper surface of one of the electrodes and electrically connected to the electrodes. The encapsulant is transparent, and is filled in the receiving space for encapsulating the light-emitting diode chip.

### BRIEF DESCRIPTION OF THE DRAWINGS

Other features and advantages of the disclosure will become apparent in the following detailed description of the embodiment with reference to the accompanying drawings, of which:

FIG. 1 is a sectional view illustrating a light-emitting diode package structure in accordance with an embodiment of the present disclosure;

FIG. 2 is a perspective view of a composite lead frame of the embodiment; and

FIG. 3 is a sectional view taken along line III-III of FIG. 2.

### DETAILED DESCRIPTION

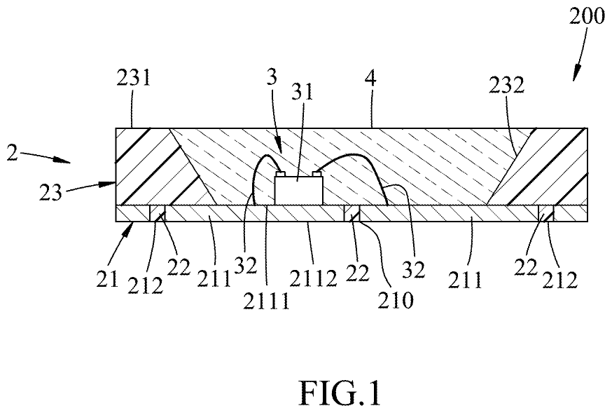

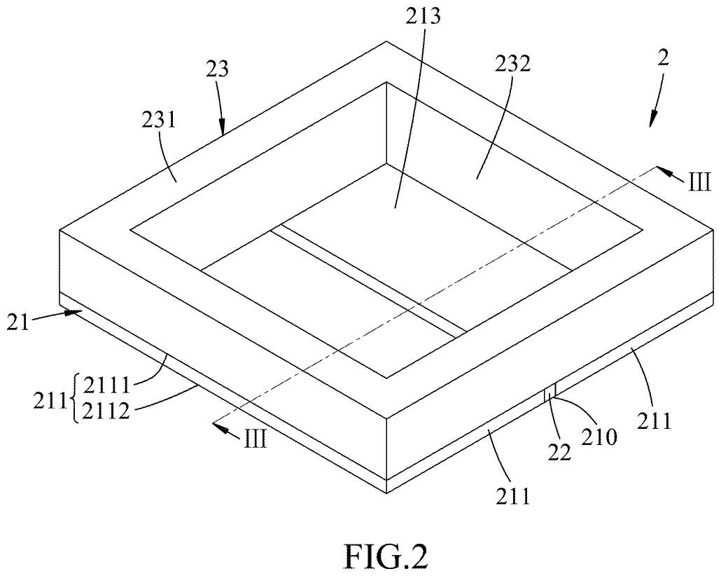

Referring to FIGS. 1 to 3, a light-emitting diode package structure 200 in accordance with an embodiment of the present disclosure includes a composite lead frame 2, a light-emitting diode unit 3, and an encapsulant 4.

The composite lead frame 2 includes a chip mounting seat 21, a plurality of fillers 22, and a reflector cup 23.

The chip mounting seat 21 is made of a material selected from copper alloy or iron-nickel alloy, and includes two electrodes 211 that are spaced apart from each other by a gap 210 and that are configured to electrically connect with the light-emitting diode unit 3. Each of the electrodes 211 has a plate shape with an upper surface 2111, a lower surface 2112 opposite to the upper surface 2111, and at least one through hole 212 extending from the upper surface 2111 to the lower surface 2112.

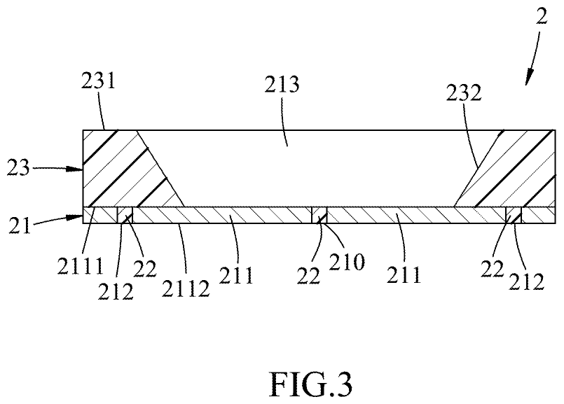

In this embodiment, each electrode 211 is formed as a square copper plate by stamping or etching, and has a plurality of the through holes 212 (only two are shown in FIGS. 1 and 3) extending from the upper surface 2111 to the lower surface 2112 of a corresponding one of the electrodes 211. However, the shape of each of the electrode 211 and the through hole 212 and the number of the through hole 212 in each electrode 211 are not limited to what is disclosed herein, and may be varied according to the requirements, as long as the electrodes 211 are electrically independent of each other and have the through holes 212.

The fillers 22 are filled in the through holes 212 of the electrodes 211 and the gap 210 between the electrodes 211. The fillers 22 may be made of a thermosetting or thermoplastic polymer material, and may be transparent or opaque. The fillers 22 have good adhesion to the reflector cup 23. To be specific, the fillers 22 may be made of epoxy resin or black resin, but is not limited thereto.

The reflector cup 23 is disposed on and cooperates with the upper surfaces 2111 of the electrodes 211 to define a receiving space 213 for receiving the light-emitting diode unit 3 and for exposing a portion of the upper surfaces 2111 of the electrodes 211.

Specifically, the reflector cup 23 is white, and corresponds in position with the through holes 212 of the electrodes 211. The reflector cup 23 has a top surface 231 distal from the upper surfaces 2111 of the electrodes 211, and an inner peripheral surface 232 tapering downwardly from an inner periphery of the top surface 231 toward the upper surfaces 2111 of the electrodes 211. The inner peripheral surface 232 has an angle of inclination greater than 90 degrees with respect to the upper surfaces 2111 of the electrodes 211. Since the fillers 22 are filled in the gap 210 between the electrodes 211 and the through holes 212 in the electrodes 211, the reflector cup 23 is not only connected to the upper surfaces 2111 of the electrodes 211, but is also simultaneously connected to the fillers 22 filled in the gap 210 and the through holes 212. Thus, adhesion between the reflector cup 23 and the electrodes 211 can be enhanced through the fillers 22. In this embodiment, the through holes 212 are formed in the electrodes 211 at positions corresponding to that of the reflector cup 23, and are not located in the receiving space 213.

The reflector cup 23 is made of a material different from that of the filler 22, and is composed of a silicon-based polymer material and a white inorganic filling material. The silicon-based polymer material includes silicone, but is not limited thereto. The white inorganic filling material is selected from one of barium sulfate and titanium dioxide, but is not limited thereto.

The light-emitting diode unit 3 includes a light-emitting diode chip 31 mounted on the upper surface 2111 of one of the electrodes 211, and a plurality of guide wires 32 for electrically connecting the light-emitting diode chip 31 to the electrodes 211.

The encapsulant 4 is transparent, and is filled in the receiving space 213 for encapsulating the light-emitting diode unit 31. The encapsulant 4 is made of an encapsulating material with high light transmittance and including epoxy resin or silicone. Thus, the encapsulant 4 will not affect the light emitting efficiency of the light-emitting diode chip 31 while protecting the light-emitting diode unit 3.

When the light-emitting diode chip 31 mounted on the chip mounting seat 21 emits light, the reflector cup 23 can reflect at least a portion of the angle of light emitted by the light-emitting diode chip 31 to change the direction of the light path, so that the light travels toward a light exit side, that is, an opening at one side of the reflector cup 23 opposite to the chip mounting seat 21, to increase the light emitting efficiency of the light-emitting diode chip 31.

The advantages of the light-emitting diode package structure 200 of this disclosure can be summarized as follows:

1. The chip mounting seat 21 is formed with the through holes 212 that are filled with the fillers 22. Therefore, through the connection of the fillers 22 and the reflector cup 23, adhesion between the reflector cup 23 and the chip mounting seat 21 can be enhanced.

2. Through the disposition and the material selection of the reflector cup 23, the light resistance and stability of the reflector cup 23 can be increased to maintain its reflectivity.

3. The reflector cup 23 is composed of a silicon-based polymer material and a white inorganic filling material, so that, apart from improving its reflectivity of light, it is also prevented from being directly irradiated by the excitation light of the light-emitting diode chip 31, which can cause photodegradation. Hence, the problem of yellowing and deterioration caused by poor weather resistance of the packaging cup of the conventional lead frame package that is made of epoxy molding compound can be resolved.

4. By using the fillers 22 to strengthen the connection between the reflector cup 23 and the chip mounting seat 21, the reflector cup 23 cannot be easily removed from the chip mounting seat 21.

While the disclosure has been described in connection with what is considered the exemplary embodiment, it is understood that this disclosure is not limited to the disclosed embodiment but is intended to cover various arrangements included within the spirit and scope of the broadest interpretation so as to encompass all such modifications and equivalent arrangements.

What is claimed is:

1. A composite lead frame for mounting a light-emitting diode chip thereon, comprising:
a chip mounting seat including at least two electrodes that are spaced apart from each other by a gap and that are configured to electrically connect with the light-emitting diode chip, each of said electrodes having a plate shape with an upper surface, a lower surface opposite to said upper surface, and at least one through hole extending from said upper surface to said lower surface;
a plurality of fillers made of polymer materials and filled in said gap and said at least one through hole; and
a reflector cup disposed on and cooperating with said upper surfaces of said electrodes to define a receiving space for receiving the light-emitting diode chip, said reflector cup being made of a material different from that of said filler and being composed of a silicon-based polymer material and a white inorganic filling material, said reflector cup being simultaneously connected to said electrodes said fillers filled in said gap and said at least one through hole.

2. The composite lead frame of claim 1, wherein said reflector cup has a top surface distal from said upper surfaces of said electrodes, and an inner peripheral surface tapering downwardly from an inner periphery of said top surface toward said upper surfaces of said electrodes and having an angle of inclination greater than 90 degrees with respect to said upper surfaces of said electrodes.

3. The composite lead frame of claim 1, wherein said silicon-based polymer material includes silicone, and said white inorganic filling material is selected from one of barium sulfate and titanium dioxide.

4. A light-emitting diode package structure, comprising:
said composite lead frame as claimed in claim 1;
a light-emitting diode unit including a light-emitting diode chip that is mounted on said upper surface of one of said electrodes and that is electrically connected to said electrodes; and
an encapsulant that is transparent and that is filled in said receiving space for encapsulating said light-emitting diode chip.

5. The light-emitting diode package structure of claim 4, wherein said light-emitting diode unit further includes a plurality of guide wires, said light-emitting diode chip being electrically connected to said electrodes through said guide wires.
